(19) United States
(12) Patent Application Publication
(10) Pub. No.: US 2011/0223434 A1
(43) Pub. Date: Sep. 15, 2011

(54) GRADIENT COMPOSITION BARRIER

(76) Inventors: Mark A. Roehrig, Stillwater, MN (US); Alan K. Nachtigal, St. Paul, MN (US); Fred B. McCormick, Maplewood, MN (US)

(21) Appl. No.: 13/128,727

(22) PCT Filed: Nov. 2, 2009
(86) PCT No.: PCT/US09/62944

§ 371 Date: May 11, 2011

Related U.S. Application Data
(60) Provisional application No. 61/115,286, filed on Nov. 17, 2008.

(51) Int. Cl. B32B 27/06; B32B 9/04; C23C 14/40

(52) U.S. Cl. 428/448; 428/688; 428/698; 428/702; 428/689; 428/697; 428/446; 204/192.14

(57) ABSTRACT

Generally, the present disclosure relates to barrier assemblies that have a reduced transmission of water vapor, and processes for making the barrier assemblies. The barrier assemblies include a substrate and an inorganic layer disposed adjacent the substrate. The inorganic layer has a composition that changes throughout the thickness of the inorganic layer. The composition includes at least a first and a second inorganic material, and the relative proportion of the first and second inorganic material in the composition changes throughout the thickness of the inorganic layer. A process for making the barrier assemblies includes dual AC sputtering of pairs of targets having different elemental compositions.

### BACKGROUND

Emerging applications such as organic light emitting diode (OLED) displays and thin film solar cells like copper indium gallium di-selenide (CIGS) require protection from water vapor. Presently, these applications use a glass encapsulating material since glass has very good barrier properties to water vapor, and is also optically transparent. However, glass is heavy, not flexible and costly due to the piecewise process used to handle individual glass parts. There is interest in developing a transparent flexible substrate with glass-like barrier properties, to replace glass in these and other applications.

Highly transparent multilayer barrier coatings have been developed to protect sensitive materials from damage due to water vapor. The water sensitive materials can be electronic components such as organic, inorganic, and hybrid organic/inorganic semiconductor devices. The multilayer barrier coatings can be deposited directly on the sensitive material, or can be deposited on a flexible transparent substrate such as a polymer film. Such a barrier film can enable lighter and potentially flexible displays and solar cells, and more cost efficient roll-to-roll encapsulation processing.

One approach for multilayer barrier coatings has been to produce multilayer oxide coatings, such as aluminum oxide or silicon oxide, interspersed with thin polymer film protective layers. Each oxide/polymer film pair is often referred to as a “dyad”, and the alternating oxide/polymer multilayer construction can contain several dyads to provide adequate protection from moisture and oxygen. Multiple passes through a coater are often needed to produce the several dyads, resulting in high production costs and an increased likelihood for film damage. Alternatively, a specialized coater with multiple coating zones can be designed to produce the several dyads in one pass through the coater. Examples of such transparent multilayer barrier coatings and processes can be found, for example, in U.S. Pat. Nos. 5,440,446 (Shaw et al.); 7,018,713 (Padiyath et al.); and 6,413,645 (Graff et al.). The oxide layers in such multilayer oxide coatings are homogeneous in composition and microstructure.

Another approach has been to produce multilayer mixed inorganic and organic layers in a graded barrier stack using a variety of chemical vapor deposition (CVD) techniques, such as described in U.S. Pat. No. 7,015,640 (Schaepkens et al.). It is believed that in this approach, the transitions between an organic layer and an oxide layer are gradiated to lessen the stresses that can develop in a sharp organic/oxide transition.

The multilayer barrier coatings produced by the aforementioned methods can greatly reduce the moisture and oxygen transport through films; however, there is a need for further improving the barrier properties above what can be accomplished using the methods described.

### SUMMARY

Generally, the present disclosure relates to barrier assemblies that have a reduced transmission of water vapor, and processes for making the barrier assemblies.

In one aspect of the disclosure, a barrier assembly includes a substrate having a first surface, and an inorganic layer adjacent the first surface. The inorganic layer includes a first inorganic material and a second inorganic material, and a ratio of the first inorganic material to the second inorganic material changes in a direction perpendicular to the first surface of the substrate. In one embodiment, the barrier assembly further includes a protective polymeric layer disposed adjacent the inorganic layer and opposite the first surface of the substrate. In another embodiment, the barrier assembly further includes a smoothing polymeric layer disposed between the first surface and the inorganic layer.

In another aspect of the disclosure, a barrier assembly includes a substrate having a first surface, and an inorganic oxide composition disposed adjacent the first surface. The inorganic oxide composition includes a first oxide of a first atomic element, and a second oxide of a second atomic element. The atomic ratio of the first atomic element to the second atomic element changes in a direction perpendicular to the first surface. In one embodiment, the barrier assembly further includes a protective polymeric layer disposed adjacent the inorganic oxide composition and opposite the first surface of the substrate. In another embodiment, the barrier assembly further includes a smoothing polymeric layer disposed between the first surface and the inorganic oxide composition.

In another aspect of the disclosure, a process for making a barrier assembly includes providing a substrate, forming a smoothing polymeric layer on the substrate, forming an inorganic layer on the smoothing polymeric layer, and forming a protective polymeric layer on the inorganic layer. The inorganic layer includes an inorganic composition that changes throughout a thickness of the inorganic layer.

These and other aspects of the present application will be apparent from the detailed description below. In no event, however, should the above summaries be construed as limitations of the claimed subject matter, which subject matter is defined solely by the attached claims and their equivalents, as may be amended during prosecution.

### BRIEF DESCRIPTION OF THE DRAWINGS

Throughout the specification reference is made to the appended drawings, where like reference numerals designate like or similar elements, and wherein:

FIG. 1 is a cross-section schematic of a barrier assembly; and

FIG. 2 is a plot showing composition change in an inorganic layer.

The figures are not necessarily to scale. Like numbers used in the figures refer to like or similar components. However, it will be understood that the use of a number to refer to a component in a given figure is not intended to limit the component in another figure labeled with the same number.

### DETAILED DESCRIPTION

The present description discloses an improved barrier assembly that can reduce the transport of water vapor and oxygen. The improved barrier assembly includes at least one inorganic layer having a composition that changes in the thickness direction of the layer, i.e. a gradient composition. The inorganic layer includes at least two inorganic materials, and the ratio of the two inorganic materials changes throughout the thickness of the inorganic layer. The ratio of two inorganic materials refers to the relative proportions of each of the inorganic materials. The ratio can be, for example, a mass ratio, a volume ratio, a concentration ratio, a molar ratio, a surface area ratio, or an atomic ratio.

Each of the inorganic materials in the gradient composition includes oxides, nitrides, carbides or borides of different atomic elements. The resulting gradient inorganic layer is an improvement over homogeneous, single component layers. Additional benefits in barrier and optical properties can also be realized when combined with thin, vacuum deposited polymer films. A multilayer gradient inorganic-polymer barrier stack can be made to enhance optical properties as well as barrier properties.

In one aspect, the barrier assembly includes a substrate, and the inorganic layer is disposed adjacent the substrate. The thickness direction of the inorganic layer is in a direction perpendicular to the surface of the substrate, and the composition of the inorganic layer changes in the direction perpendicular to the substrate. In one embodiment, the substrate can include a moisture sensitive material, such as an electronic device. It is to be understood that the inorganic layer can further include additional organic or inorganic materials which may or may not remain at a constant concentration throughout the thickness direction.

In one embodiment, the barrier assembly further includes a smoothing polymeric layer disposed between the substrate and the inorganic layer. In another embodiment, the barrier assembly further includes a protective polymeric layer disposed on the inorganic layer. The inorganic layer and protective polymeric layer form a “dyad”, and in one embodiment, the barrier assembly can include more than one dyad, forming a multilayer barrier assembly. Each of the inorganic layers in a multilayer barrier assembly, such as a barrier assembly that includes more than one dyad, can be the same or different.

The barrier assembly can be fabricated by deposition of the various layers onto the substrate, in a roll-to-roll vacuum chamber similar to the system described in U.S. Pat. Nos. 5,440,446 (Shaw et al.) and 7,018,713 (Padiyath, et al.). The deposition of the layers can be in-line, and in a single pass through the system. In some cases, the barrier assembly can pass through the system several times, to form a multilayer barrier assembly having several dyads.

The first and second inorganic materials can be oxides, nitrides, carbides or borides of metal or nonmetal atomic elements, or combinations of metal or nonmetal atomic elements. By “metal or nonmetal” atomic elements is meant atomic elements selected from the periodic table Groups IIA, IIIA, IVA, VA, VIA, VIIA, IB, or IIB, metals of Groups IIIB, IVB, or VB, rare-earth metals, or combinations thereof. Suitable inorganic materials include, for example, metal oxides, metal nitrides, metal carbides, metal oxynitrides, metal oxyborides, and combinations thereof, e.g., silicon oxides such as silica, aluminum oxides such as alumina, titanium oxides such as titania, indium oxides, tin oxides, indium tin oxide (“ITO”), tantalum oxide, zirconium oxide, niobium oxide, aluminum nitride, silicon nitride, boron nitride, aluminum oxynitride, silicon oxynitride, boron oxynitride, zirconium oxyboride, titanium oxyboride, and combinations thereof. ITO is an example of a special class of ceramic materials that can become electrically conducting with the proper selection of the relative proportions of each elemental constituent.

For purposes of clarity, the inorganic layer described in the following discussion is directed toward a composition of oxides; however, it is to be understood that the composition can include any of the oxides, nitrides, carbides, borides, oxynitrides, oxyborides and the like described above.

In one embodiment of the inorganic layer, the first inorganic material is silicon oxide, and the second inorganic material is aluminum oxide. In this embodiment, the atomic ratio of silicon to aluminum changes throughout the thickness of the inorganic layer, e.g., there is more silicon than aluminum near a first surface of the inorganic layer, gradually becoming more aluminum than silicon as the distance from the first surface increases. In one embodiment, the atomic ratio of silicon to aluminum can change monotonically as the distance from the first surface increases, i.e., the ratio either increases or decreases as the distance from the first surface increases, but the ratio does not both increase and decrease as the distance from the first surface increases. In another embodiment, the ratio does not increase or decrease monotonically, i.e. the ratio can increase in a first portion, and decrease in a second portion, as the distance from the first surface increases. In this embodiment, there can be several increases and decreases in the ratio as the distance from the first surface increases, and the ratio is non-monotonic. A change in the inorganic oxide concentration from one oxide species to another throughout the thickness of the inorganic layer results in improved barrier performance, as measured by water vapor transmission rate.

In addition to improved barrier properties, the gradient composition can be made to exhibit other unique optical properties while retaining improved barrier properties. The gradient change in composition of the layer produces corresponding change in refractive index through the layer. The materials can be chosen such that the refractive index can change from high to low, or vice versa. For example, going from a high refractive index to a low refractive index can allow light traveling in one direction to easily pass through the layer, while light travelling in the opposite direction may be reflected by the layer. The refractive index change can be used to design layers to enhance light extraction from a light emitting device being protected by the layer. The refractive index change can instead be used to pass light through the layer and into a light harvesting device such as a solar cell. Other optical constructions, such as band pass filters, can also be incorporated into the layer while retaining improved barrier properties.

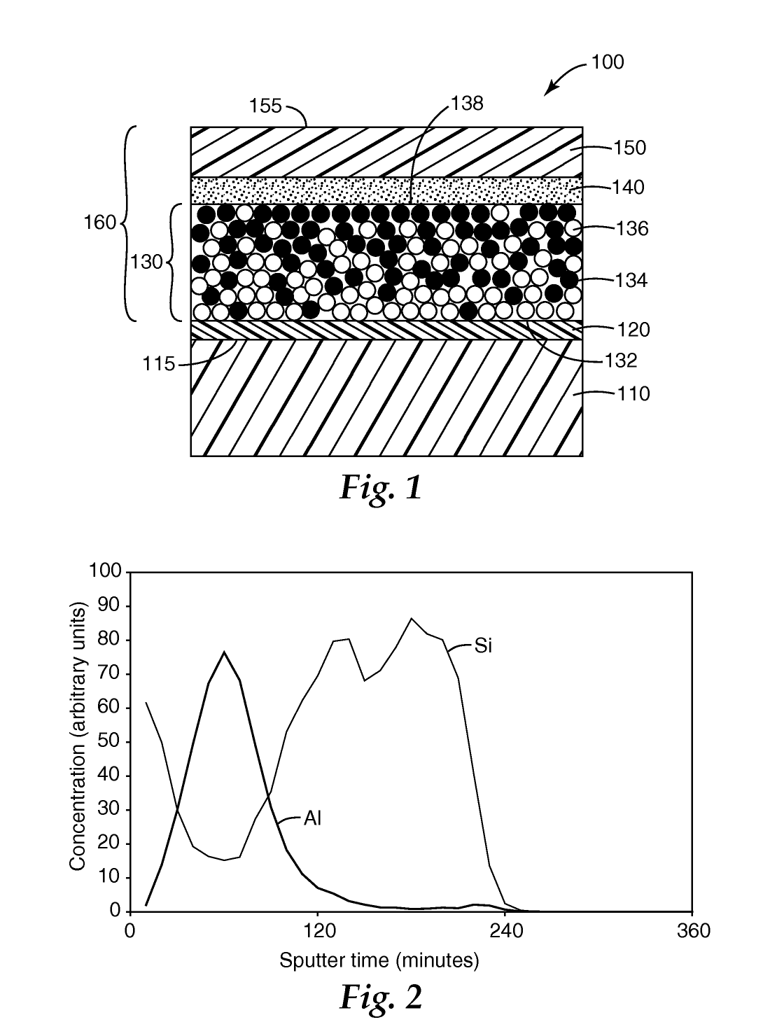

FIG. 1 shows a schematic cross-section of a barrier assembly 100 according to one aspect of the disclosure. In one embodiment, barrier assembly 100 includes a substrate 110 having a first surface 115, and an inorganic layer 130 disposed adjacent to first surface 115. In another embodiment, barrier assembly 100 further includes an optional smoothing polymeric layer 120 disposed between the inorganic layer 130 and the first surface 115, and a dyad 160 disposed on optional smoothing polymeric layer 120. In one embodiment, dyad 160 includes an optional protective polymeric layer 150 disposed adjacent inorganic layer 130 and opposite substrate 110, and an optional additional inorganic layer 140 disposed between inorganic layer 130 and protective polymeric layer 150. In another embodiment, barrier assembly 100 can form a multilayer barrier assembly that includes additional dyads (not shown, but similar to dyad 160), disposed adjacent a top surface 155 of protective polymeric layer 150.

Substrate 110 can be a flexible transparent substrate, such as a flexible light transmissive polymeric film. Flexible light-transmissive polymeric films can have a visible light transmission greater than about 70% at 550 nm. The polymeric film can be heat-stabilized, using heat setting, annealing under tension, or other techniques that will discourage shrinkage up to at least the heat stabilization temperature when the polymeric film is not constrained. Polyethylene terephthalate (PET) can be used, however it can be preferable to use a heat stabilized polyethylene terephthalate (HSPET). Other polymeric films can include, for example, polyesters, polymethyl methacrylate (PMMA), styrene/acrylonitrile (SAN), styrene/maleic anhydride (SMA), polyethylene naphthalate (PEN), heat stabilized PEN (HSPEN), polyoxymethylene (POM), polyvinylnaphthalene (PVN), polyetheretherketone (PEEK), polyaryletherketone (PAEK), high Tg fluoropolymers (e.g., DYNEON™ HTE terpolymer of hexafluoropropylene, tetrafluoroethylene, and ethylene), polycarbonate (PC), poly α-methyl styrene, polyarylate (PAR), polysulfone (PSul), polyphenylene oxide (PPO), polyetherimide (PEI), polyarylsulfone (PAS), poly ether sulfone (PES), polyamideimide (PAI), polyimide and polyphthalamide. In some embodiments, where material costs are important, polymer films made of PET, HSPET, PEN and HSPEN can be used. In some embodiments, where barrier performance is paramount, polymer films made of more expensive materials can be used. The polymer film can have any suitable thickness, for example about 0.01 to about 1 mm.

Returning to FIG. 1, inorganic layer 130 includes a first inorganic surface 132 adjacent first surface 115 of substrate 110, and a second inorganic surface 138. Inorganic layer 130 has a composition that includes a first inorganic material 134 and a second inorganic material 136. The relative proportions of first and second inorganic materials 134, 136 changes as a gradient throughout the thickness of inorganic layer 130 in a direction perpendicular to first surface 115 of substrate 110, for example, from the first inorganic surface 132 to the second inorganic surface 138. FIG. 1 is a schematic cross section, and as such the depicted size, shape and distribution of both first inorganic material 134 and second inorganic material 136 are intended to show that the composition changes throughout the thickness, and not indicate any restrictions on actual size, shape or distribution of materials. In one embodiment (shown), the ratio of the second inorganic material 136 to the first inorganic material 134 is higher close to first inorganic surface 132 and the ratio decreases in the direction toward second inorganic surface 138. In another embodiment (not shown), the ratio of the first inorganic material 134 to the second inorganic material 136 is higher close to first inorganic surface 132 and the ratio decreases in the direction toward second inorganic surface 138.

The inorganic layer can be formed using techniques employed in the film metalizing art such as sputtering (e.g., cathode or planar magnetron sputtering), evaporation (e.g., resistive or electron beam evaporation), chemical vapor deposition, plating and the like. In one aspect, the inorganic layer is formed using sputtering, e.g., reactive sputtering. Enhanced barrier properties have been observed when the inorganic layer is formed by a high energy deposition technique such as sputtering compared to lower energy techniques such as conventional chemical vapor deposition processes. Without being bound by theory, it is believed that the enhanced properties are due to the condensing species arriving at the substrate with greater kinetic energy as occurs in sputtering, leading to a lower void fraction as a result of compaction.

In one aspect, the sputter deposition process can use dual targets powered by an alternating current (AC) power supply in the presence of a gaseous atmosphere having inert and reactive gasses, for example argon and oxygen, respectively. The AC power supply alternates the polarity to each of the dual targets such that for half of the AC cycle one target is the cathode and the other target is the anode. On the next cycle the polarity switches between the dual targets. This switching occurs at a set frequency, for example about 40 kHz, although other frequencies can be used. Oxygen that is introduced into the process forms oxide layers on both the substrate receiving the inorganic composition, and also on the surface of the target. The dielectric oxides can become charged during sputtering, thereby disrupting the sputter deposition process. Polarity switching can neutralize the surface material being sputtered from the targets, and can provide uniformity and better control of the deposited material.

In one aspect, each of the targets used for dual AC sputtering can include a single metal or nonmetal element, or a mixture of metal and/or nonmetal elements. A first portion of the inorganic layer closest to the moving substrate is deposited using the first set of sputtering targets. The substrate then moves proximate the second set of sputtering targets and a second portion of the inorganic layer is deposited on top of the first portion using the second set of sputtering targets. The composition of the inorganic layer changes in the thickness direction through the layer.

In another aspect, the sputter deposition process can use targets powered by direct current (DC) power supplies in the presence of a gaseous atmosphere having inert and reactive gasses, for example argon and oxygen, respectively. The DC power supplies supply power (e.g. pulsed power) to each cathode target independent of the other power supplies. In this aspect, each individual cathode target and the corresponding material can be sputtered at differing levels of power, providing additional control of composition through the layer thickness. The pulsing aspect of the DC power supplies is similar to the frequency aspect in AC sputtering, allowing control of high rate sputtering in the presence of reactive gas species such as oxygen. Pulsing DC power supplies allow control of polarity switching, can neutralize the surface material being sputtered from the targets, and can provide uniformity and better control of the deposited material.

In one embodiment, improved control during sputtering can be achieved by using a mixture, or atomic composition, of elements in each target, for example a target may include a mixture of aluminum and silicon. In another embodiment, the relative proportions of the elements in each of the targets can be different, to readily provide for a varying atomic ratio throughout the inorganic layer. In one embodiment, for example, a first set of dual AC sputtering targets may include a 90/10 mixture of silicon and aluminum, and a second set of dual AC sputtering targets may include a 75/25 mixture of aluminum and silicon. In this embodiment, a first portion of the inorganic layer can be deposited with the 90% Si/10% Al target, and a second portion can be deposited with the 75% Al/25% Si target. The resulting inorganic layer has a gradient composition that changes from about 90% Si to about 25% Si (and conversely from about 10% Al to about 75% Al) through the thickness of the inorganic layer.

In typical dual AC sputtering, homogeneous oxide layers are formed, and barrier performance from these homogeneous oxide layers suffer due to defects in the layer at the micro and nano-scale. One cause of these small scale defects is inherently due to the way the oxide grows into grain boundary structures, which then propagate through the thickness of the film. Without being bound by theory, it is believed several effects contribute to the improved barrier properties of the gradient composition barriers described herein. One effect can be that greater densification of the mixed oxides occurs in the gradient region, and any paths that water vapor could take through the oxide are blocked by this densification. Another effect can be that by varying the composition of the oxide materials, grain boundary formation can be disrupted resulting in a microstructure of the film that also varies through the thickness of the oxide layer. Another effect can be that the concentration of one oxide gradually decreases as the other oxide concentration increases through the thickness, reducing the probability of forming small-scale defect sites. The reduction of defect sites can result in a coating having reduced transmission rates of water permeation.

Returning to FIG. 1, the optional smoothing polymeric layer 120 and optional protective polymeric layer 150 can include any polymer suitable for deposition in a thin film. In one aspect, for example, both the smoothing polymeric layer 120 and the protective polymeric layer can be formed from various monomers that include acrylates or methacrylates such as urethane acrylates, isobornyl acrylate, dipentaerythritol pentaacrylates, epoxy acrylates, epoxy acrylates blended with styrene, di-trimethylolpropane tetraacrylates, diethylene glycol diacrylates, 1,3-butylene glycol diacrylate, pentaacrylate esters, pentaerythritol tetraacrylates, pentaerythritol triacrylates, ethoxylated (3) trimethylolpropane triacrylates, ethoxylated (3) trimethylolpropane triacrylates, alkoxylated trifunctional acrylate esters, dipropylene glycol diacrylates, neopentyl glycol diacrylates, ethoxylated (4) bisphenol a dimethacrylates, cyclohexane dimethanol diacrylate esters, isobornyl methacrylate, cyclic diacrylates and tris (2-hydroxy ethyl) isocyanurate triacrylate, acrylates of the foregoing methacrylates and methacrylates of the foregoing acrylates.

Both smoothing and protective polymeric layers can be formed by applying a layer of a monomer or oligomer to the substrate and crosslinking the layer to form the polymer in situ, e.g., by flash evaporation and vapor deposition of a radiation-crosslinkable monomer, followed by crosslinking using, for example, an electron beam apparatus, UV light source, electrical discharge apparatus or other suitable device. Coating efficiency can be improved by cooling the substrate. The monomer or oligomer can also be applied to the substrate using conventional coating methods such as roll coating (e.g., gravure roll coating) or spray coating (e.g., electrostatic spray coating), then crosslinked as set out above. Both polymer layers can also be formed by applying a layer containing an oligomer or polymer in solvent and drying the thus-applied layer to remove the solvent. Plasma polymerization may also be employed in some cases. Most preferably, the polymer layers are formed by flash evaporation and vapor deposition followed by crosslinking in situ, e.g., as described in U.S. Pat. No. 4,696,719 (Bischoff), U.S. Pat. No. 4,722,515 (Ham), U.S. Pat. No. 4,842,893 (Yializis et al.), U.S. Pat. No. 4,954,371 (Yializis), U.S. Pat. No. 5,018,048 (Shaw et al.), U.S. Pat. No. 5,032,461 (Shaw et al.), U.S. Pat. No. 5,097,800 (Shaw et al.), U.S. Pat. No. 5,125,138 (Shaw et al.), U.S. Pat. No. 5,440,446 (Shaw et al.), U.S. Pat. No. 5,547,908 (Furuzawa et al.), U.S. Pat. No. 6,045,864 (Lyons et al.), U.S. Pat. No. 6,231,939 (Shaw et al. and U.S. Pat. No. 6,214,422 (Yializis); in published PCT Application No. WO 00/26973 (Delta V Technologies, Inc.); in D. G. Shaw and M. G. Langlois, “A New Vapor Deposition Process for Coating Paper and Polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum deposited polymer/metal multilayer films for optical application”, Thin Solid Films 270, 43-48 (1995); and in J. D. Affinito, M. E. Gross, C. A. Coronado, G. L. Graff, E. N. Greenwell and P. M. Martin, “Polymer-Oxide Transparent Barrier Layers”, Society of Vacuum Coaters 39th Annual Technical Conference Proceedings (1996).

The smoothness and continuity of each polymer layer (and also each inorganic layer) and its adhesion to the underlying layer preferably can be enhanced by appropriate pretreatment. Examples of a suitable pretreatment regimen include an electrical discharge in the presence of a suitable reactive or non-reactive atmosphere (e.g., plasma, glow discharge, corona discharge, dielectric barrier discharge or atmospheric pressure discharge); chemical pretreatment or flame pretreatment. These pretreatments help make the surface of the underlying layer more receptive to formation of the subsequently applied polymeric (or inorganic) layer. Plasma pretreatment can be particularly useful. A separate adhesion promotion layer which may have a different composition than the polymeric layer may also be utilized atop an underlying layer to improve interlayer adhesion. The adhesion promotion layer can be, for example, a separate polymeric layer or a metal-containing layer such as a layer of metal, metal oxide, metal nitride or metal oxynitride. The adhesion promotion layer may have a thickness of a few nm (e.g., 1 or 2 nm) to about 50 nm, and can be thicker if desired.

The desired chemical composition and thickness of the smoothing polymeric layer will depend in part on the nature and surface topography of the substrate. The thickness preferably is sufficient to provide a smooth, defect-free surface to which the subsequent inorganic layer can be applied. For example, the smoothing polymeric layer may have a thickness of a few nm (e.g., 2 or 3 nm) to about 5 micrometers, and can be thicker if desired.

As described elsewhere, the barrier assembly can include the inorganic layer deposited directly on a substrate that includes a moisture sensitive device, a process often referred to as direct encapsulation. The moisture sensitive device can be, for example, an organic, inorganic, or hybrid organic/inorganic semiconductor device including, for example, a photovoltaic device such as a CIGS; a display device such as an OLED, electrochromic, or an electrophoretic display; an OLED or other electroluminescent solid state lighting device, or others. Flexible electronic devices can be encapsulated directly with the gradient composition oxide layer. For example, the devices can be attached to a flexible carrier substrate, and a mask can be deposited to protect electrical connections from the inorganic layer deposition. A smoothing polymeric layer and the inorganic layer can be deposited as described elsewhere, and the mask can then be removed, exposing the electrical connections.

Exemplary embodiments will now be described in the following illustrative examples, in which all parts and percentages are by weight unless otherwise indicated.

### EXAMPLES

Examples of barrier assemblies were made on a vacuum coater similar to the coater described in U.S. Pat. Nos. 5,440,446 (Shaw et al.) and 7,018,713 (Padiyath, et al.). A gradient inorganic oxide layer was made by two dual AC reactive sputter deposition cathodes employing two 40 kHz dual AC power supplies. Each pair of dual cathodes had two Si(90%)/Al(10%) targets and two Al(75%)/Si(25%) targets connected to separate power supplies. The voltage for each pair of cathodes during sputtering was controlled by a feed-back control loop that monitored the voltage and controlled the oxygen flow such that the voltage would remain high and not crash the target voltage.

### Example 1

### Barrier Assembly on Polyethylene Terephthalate (PET)

A PET substrate film was covered with a stack of an acrylate smoothing layer, a gradient inorganic oxide (GIO), a Silicon Oxide (SiOₓ), and an acrylate protective layer. The GIO had a depth composition varying between a silicon-rich oxide adjacent the smoothing layer, and an aluminum-rich oxide adjacent the protective layer. The individual layers were formed as follows:

(Layer 1—smoothing polymeric layer) A 244 meter long roll of 0.051 mm thick×305 mm wide HLA PET film (commercially available from DuPont-Teijin Films) was loaded into a roll-to-roll vacuum processing chamber. The chamber was pumped down to a pressure of 7×10⁻⁵ Torr. The web speed was maintained at 3 meters/min while maintaining the backside of the film in contact with a coating drum chilled to −10° C. With the film in contact with the drum, the film surface was coated with a tricyclodecane dimethanol diacrylate (SR-833S, commercially available from Sartomer). The diacrylate was vacuum degassed to a pressure of 20 mTorr prior to coating, and pumped at a flow rate of 0.7 mL/min through an ultrasonic atomizer operated at a frequency of 60 kHz into a heated vaporization chamber maintained at 260° C. The resulting monomer vapor stream condensed onto the film surface and was electron beam crosslinked using a plasma-generated beam operated at 9.5 kV and 2.9 mA to form an 830 nm acrylate layer.

(Layer 2—inorganic layer) Immediately after the acrylate deposition and with the film still in contact with the drum, a GIO layer was sputter-deposited atop a 162 meter length of the acrylate-coated web surface. Two alternating current (AC) power supplies were used to control two pairs of cathodes, with each cathode housing two targets. The first cathode contained two 90% Si/10% Al targets and the second cathode contained two 75% Al/25% Si targets (targets commercially available from Academy Precision Materials). During sputter deposition, the voltage signal from each power supply was used as an input for a proportional-integral-differential control loop to maintain a predetermined oxygen flow to each cathode. The first AC power supply sputtered the 90% Si/10% Al targets using 5000 watts of power, with a gas mixture containing 130 sccm argon and 40 sccm oxygen at a sputter pressure of 2 millitorr. The second AC power supply sputtered the 75% Al/25% Si target pair using 5000 watts of power, with a gas mixture containing 130 sccm argon and 23 sccm oxygen at a sputter pressure of 2 millitorr. This provided a 35 nm thick GIO layer deposited atop the Layer 1 acrylate.

(Layer 3—inorganic layer) Immediately after the GIO deposition and with the film still in contact with the drum, a sub-oxide of silicon (SiOₓ, where x<2) tie-layer was sputter deposited atop the same 162 meter length of the GIO and acrylate coated web surface using a 99.999% Si target (commercially available from Academy Precision Materials). The SiOₓ was sputtered using 500 watts of power, with a gas mixture containing 200 sccm argon and 5 sccm oxygen at a sputter pressure of 1.5 millitorr, to provide a SiOₓ layer approximately 1 to 3 nm thick atop Layer 2.

(Layer 4—protective polymeric layer) Immediately after the SiOₓ layer deposition and with the film still in contact with the drum, a second acrylate (same acrylate as in layer 1) was coated and crosslinked on the same 162 meter web length using the same general conditions as for Layer 1, but with these exceptions. Electron beam crosslinking was carried out using a multi-filament cure gun operated at 9 kV and 2.06 mA. This provided an 830 nm acrylate layer atop Layer 3.

The resulting four layer stack on the polymeric substrate exhibited an average spectral transmission Tvis=89% (determined by averaging the percent transmission T between 400 nm and 700 nm) measured at a 0° angle of incidence. A water vapor transmission rate was measured in accordance with ASTM F-1249 at 50° C. and 100% RH and the result was below the 0.005 g/m²/day lower detection limit rate of the MOCON PERMATRAN-W® Model 700 WVTR testing system (commercially available from MOCON, Inc).

### Example 2

### Depth Profile of Gradient Inorganic Layer

A three layer stack on a polymer substrate was prepared by depositing Layers 1, 2, and 3 in the same manner as Example 1, but without depositing the Layer 4 acrylate. The absence of a top layer acrylate allowed the resulting three layer stack to be measured using time-of-flight secondary ion mass spectrometry (TOF-SIMS) on a TOF-SIMS instrument (commercially available from ION-TOF, Germany). A positive ion analysis was performed using a pulsed 25 keV Bi⁺ primary ion beam, with a beam diameter of about 3 μm, and an analysis area of 250 μm×250 μm. Depth profiles were carried out using a 2 keV O2⁺ ion beam rastered at 10×10 mm. FIG. 2 is a plot showing composition change in an inorganic layer. The concentration (y-axis) of aluminum and silicon as a function of sputter time (x-axis) is shown in FIG. 2. Sputter time, in the TOF-SIMS apparatus, correlates to the depth through the coating. FIG. 2 is a plot of the composition of the inorganic oxide layer, measured from the last deposited material (at left in plot, corresponds to optional additional inorganic layer 140 shown in FIG. 1) to the first deposited material (at right in plot, corresponds to first inorganic surface 132 shown in FIG. 1). As shown in FIG. 2, the concentration of the aluminum (Al) decreases at around 90 minutes, and the concentration of silicon (Si) begins to increase.

The disclosed barrier assemblies can be used anywhere that protection from moisture is desired, including but not limited to displays such as those using OLEDs, electrochromics, or electrophoretics; semiconductors such as photovoltaics and thin film transistors; electronic paper; signs; lighting including OLED and other electroluminescent solid state lighting; packaging including food, pharmaceutical and chemical packaging; and the like.

Unless otherwise indicated, all numbers expressing feature sizes, amounts, and physical properties used in the specification and claims are to be understood as being modified by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A barrier assembly, comprising:
a substrate having a first surface; and
an inorganic layer adjacent the first surface, the inorganic layer comprising:
a first inorganic material, and
a second inorganic material,
wherein a ratio of the first inorganic material to the second inorganic material changes in a direction perpendicular to the first surface.

2. The barrier assembly of claim 1, further comprising a protective polymeric layer disposed adjacent the inorganic layer and opposite the first surface of the substrate.

3. The barrier assembly of claim 1, further comprising a smoothing polymeric layer disposed between the first surface and the inorganic layer.

4. The barrier assembly of claim 1, wherein the inorganic layer is visible light transmissive.

5. The barrier assembly of claim 1, wherein the first inorganic material and the second inorganic material comprise oxides, nitrides, carbides or borides of atomic elements from Groups IIA, IIIA, IVA, VA, VIA, VIIA, IB, or IIB, metals of Groups IIIB, IVB, or VB, rare-earth metals, or combinations thereof.

6. The barrier assembly of claim 5, wherein the first inorganic material comprises a first atomic element, the second inorganic material comprises a second atomic element different from the first atomic element, and the ratio is an atomic ratio of the first atomic element to the second atomic element.

7. The barrier assembly of claim 6, wherein the first atomic element comprises silicon and the second atomic element comprises aluminum.

8. (canceled)

9. The barrier assembly of claim 1, wherein the ratio changes from greater than 0.7 to less than 0.3 in the direction perpendicular to the first surface.

10. (canceled)

11. The barrier assembly of claim 2, further comprising a third inorganic material disposed between the inorganic layer and the protective polymeric layer.

12. The barrier assembly of claim 11, wherein the third inorganic material comprises oxides, nitrides, carbides or borides of atomic elements of Groups IIA, IIIA, IVA, VA, VIA, VIIA, IB, or IIB, metals of Groups IIIB, IVB, or VB, rare-earth metals, or combinations thereof.

13-19. (canceled)

20. A barrier assembly, comprising:
a substrate having a first surface; and
an inorganic oxide composition disposed adjacent the first surface, the inorganic oxide composition comprising:
a first oxide of a first atomic element,
a second oxide of a second atomic element,
wherein an atomic ratio of the first atomic element to the second atomic element changes in a direction perpendicular to the first surface.

21. The barrier assembly of claim 20, further comprising a protective polymeric layer disposed adjacent the inorganic oxide composition and opposite the first surface of the substrate.

22. The barrier assembly of claim 20, further comprising a smoothing polymeric layer disposed between the first surface and the inorganic oxide composition.

23. The barrier assembly of claim 21, further comprising a third inorganic oxide disposed between the inorganic oxide composition and the protective polymeric layer.

24. The barrier assembly of claim 23, wherein the oxide of the first atomic element, the oxide of the second atomic element, and the third inorganic oxide comprise silicon oxide or aluminum oxide.

25. A process for making a barrier assembly, comprising:
providing a substrate;
forming a smoothing polymeric layer on the substrate;
forming an inorganic layer on the smoothing polymeric layer, the inorganic layer comprising an inorganic composition that changes throughout a thickness of the inorganic layer; and
forming a protective polymeric layer on the inorganic layer.

26. The process of claim 25, wherein forming the inorganic layer comprises dual alternating current (AC) sputtering of a first pair of sputtering targets followed by dual AC sputtering of a second pair of sputtering targets.

27. The process of claim 26, wherein the first pair of sputtering targets comprise a first atomic composition and the second pair of sputtering targets comprise a second atomic composition different from the first atomic composition.

28. The process of claim 26, wherein the first pair of sputtering targets are in a first gaseous atmosphere, and the second pair of sputtering targets are in a second gaseous atmosphere different from the first gaseous atmosphere.

29. (canceled)

30. The process of claim 25, wherein the substrate is provided on a roll, and the forming steps are performed continuously, in order, as the substrate is unrolled.

31-33. (canceled)
